(19) United States
(12) Patent Application Publication
(10) Pub. No.: US 2020/0227458 A1
(43) Pub. Date: Jul. 16, 2020

(54) IMAGE SENSORS WITH DIFFRACTIVE LENSES IN A SEMICONDUCTOR SUBSTRATE

(71) Applicant: SEMICONDUCTOR COMPONENTS INDUSTRIES, LLC, Phoenix, AZ (US)

(72) Inventor: Byounghee LEE, Meridian, ID (US)

(73) Assignee: SEMICONDUCTOR COMPONENTS INDUSTRIES, LLC, Phoenix, AZ (US)

(21) Appl. No.: 16/245,965

(22) Filed: Jan. 11, 2019

(51) Int. Cl. H01L 27/146

(52) U.S. Cl. CPC H01L 27/14627; H01L 27/1463; H01L 31/02327; H01L 27/1462; H01L 27/14643

(57) ABSTRACT

An image sensor may include an array of imaging pixels. Each imaging pixel may have a photosensitive area formed in a semiconductor substrate that is covered by a respective microlens that focuses light onto the photosensitive area. Each imaging pixel may also include a diffractive lens formed in the semiconductor substrate. The diffractive lens may spread light to increase the average path length of incident light within the photosensitive area and increase efficiency of the pixel. An additional diffractive lens may be formed over the semiconductor substrate to focus light onto the diffractive lens and further improve efficiency. Multiple diffractive lenses may be formed in the semiconductor substrate of a single imaging pixel. The diffractive lenses may be multipart diffractive lenses.

### BACKGROUND

This relates generally to image sensors and, more particularly, to image sensors having lenses to focus light.

Image sensors are commonly used in electronic devices such as cellular telephones, cameras, and computers to capture images. In a typical arrangement, an electronic device is provided with an array of image pixels arranged in pixel rows and pixel columns. Each image pixel in the array includes a photodiode that is coupled to a floating diffusion region via a transfer gate. Each pixel receives incident photons (light) and converts the photons into electrical signals. Column circuitry is coupled to each pixel column for reading out pixel signals from the image pixels. Image sensors are sometimes designed to provide images to electronic devices using a Joint Photographic Experts Group (JPEG) format.

Conventional image sensors sometimes include a color filter element and a microlens above each pixel. The microlenses of conventional image sensors typically have curved surfaces and use refraction to focus light on an underlying photodiode. However, these types of microlenses may result in light passing through a respective photodiode with a shorter than desired path length.

It would therefore be desirable to provide improved lens arrangements for image sensors.

### BRIEF DESCRIPTION OF THE DRAWINGS

FIG. 1 is a schematic diagram of an illustrative electronic device that may include an image sensor in accordance with an embodiment.

FIG. 2 is a diagram of an illustrative pixel array and associated readout circuitry for reading out image signals from the pixel array in accordance with an embodiment.

FIG. 3A is a cross-sectional side view of an illustrative focusing diffractive lens with a greater index of refraction than the surrounding medium in accordance with an embodiment.

FIG. 3B is a cross-sectional side view of an illustrative defocusing diffractive lens with a lower index of refraction than the surrounding medium in accordance with an embodiment.

FIGS. 4A and 4B are cross-sectional side views of illustrative diffractive lenses showing how the thickness of the diffractive lens may be adjusted to change the response to incident light in accordance with an embodiment.

FIG. 5A is a cross-sectional side view of an illustrative multipart focusing diffractive lens with two portions having greater indices of refraction than the surrounding medium in accordance with an embodiment.

FIG. 5B is a cross-sectional side view of an illustrative multipart defocusing diffractive lens with two portions having lower indices of refraction than the surrounding medium in accordance with an embodiment.

FIG. 5C is a cross-sectional side view of an illustrative multipart focusing diffractive lens with three portions having greater indices of refraction than the surrounding medium in accordance with an embodiment.

FIG. 5D is a cross-sectional side view of an illustrative asymmetric multipart focusing diffractive lens with two portions having greater indices of refraction than the surrounding medium in accordance with an embodiment.

FIG. 5E is a cross-sectional side view of an illustrative asymmetric multipart defocusing diffractive lens with two portions having lower indices of refraction than the surrounding medium in accordance with an embodiment.

FIG. 6 is a cross-sectional side view of an illustrative image sensor that includes imaging pixels with microlenses and no diffractive lenses in accordance with an embodiment.

FIG. 7 is a cross-sectional side view of an illustrative image sensor that includes imaging pixels with microlenses and diffractive lenses formed in a semiconductor substrate in accordance with an embodiment.

FIG. 8 is a cross-sectional side view of an illustrative image sensor that includes imaging pixels with microlenses and multiple-edge diffractive lenses formed in a semiconductor substrate in accordance with an embodiment.

FIG. 9 is a cross-sectional side view of an illustrative image sensor that includes imaging pixels with single-edge diffractive lenses formed in a semiconductor substrate and over the semiconductor substrate in accordance with an embodiment.

FIG. 10 is a cross-sectional side view of an illustrative image sensor that includes imaging pixels with multiple-edge diffractive lenses formed in a semiconductor substrate and single-edge diffractive lenses formed over the semiconductor substrate in accordance with an embodiment.

FIG. 11 is a cross-sectional side view of an illustrative image sensor that includes imaging pixels with multiple-edge diffractive lenses formed in a semiconductor substrate and over the semiconductor substrate in accordance with an embodiment.

FIG. 12 is a cross-sectional side view of an illustrative image sensor that has multiple diffractive lenses formed in the semiconductor substrate of each imaging pixel and multiple diffractive lenses formed over the semiconductor substrate of each imaging pixel in accordance with an embodiment.

FIG. 13 is a top view of an illustrative image sensor having a single diffractive lens formed in the semiconductor substrate of each imaging pixel in accordance with an embodiment.

FIG. 14 is a top view of an illustrative image sensor having five diffractive lenses formed in the semiconductor substrate of each imaging pixel in accordance with an embodiment.

FIG. 15 is a top view of an illustrative image sensor having nine diffractive lenses formed in the semiconductor substrate of each imaging pixel in accordance with an embodiment.

### DETAILED DESCRIPTION

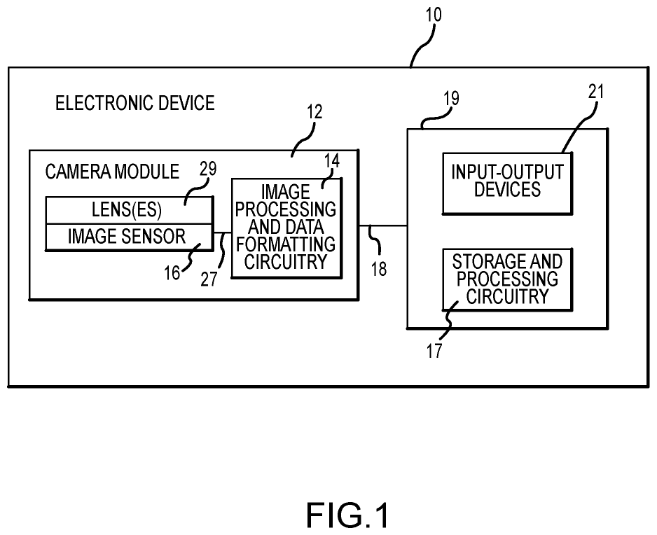

Embodiments of the present invention relate to image sensors with pixels that include diffractive lenses. An electronic device with a digital camera module is shown in FIG. 1. Electronic device 10 may be a digital camera, a computer, a cellular telephone, a medical device, or other electronic device. Camera module 12 (sometimes referred to as an imaging device) may include image sensor 16 and one or more lenses 29. During operation, lenses 29 (sometimes referred to as optics 29) focus light onto image sensor 16. Image sensor 16 includes photosensitive elements (e.g., pixels) that convert the light into digital data. Image sensors may have any number of pixels (e.g., hundreds, thousands, millions, or more). A typical image sensor may, for example, have millions of pixels (e.g., megapixels). As examples, image sensor 16 may include bias circuitry (e.g., source follower load circuits), sample and hold circuitry, correlated double sampling (CDS) circuitry, amplifier circuitry, analog-to-digital (ADC) converter circuitry, data output circuitry, memory (e.g., buffer circuitry), address circuitry, etc.

Still and video image data from image sensor 16 may be provided to image processing and data formatting circuitry 14 via path 27. Image processing and data formatting circuitry 14 may be used to perform image processing functions such as automatic focusing functions, depth sensing, data formatting, adjusting white balance and exposure, implementing video image stabilization, face detection, etc. For example, during automatic focusing operations, image processing and data formatting circuitry 14 may process data gathered by phase detection pixels in image sensor 16 to determine the magnitude and direction of lens movement (e.g., movement of lens 29) needed to bring an object of interest into focus.

Image processing and data formatting circuitry 14 may also be used to compress raw camera image files if desired (e.g., to Joint Photographic Experts Group or JPEG format). In a typical arrangement, which is sometimes referred to as a system on chip (SOC) arrangement, camera sensor 16 and image processing and data formatting circuitry 14 are implemented on a common integrated circuit. The use of a single integrated circuit to implement camera sensor 16 and image processing and data formatting circuitry 14 can help to reduce costs. This is, however, merely illustrative. If desired, camera sensor 14 and image processing and data formatting circuitry 14 may be implemented using separate integrated circuits. If desired, camera sensor 16 and image processing circuitry 14 may be formed on separate semiconductor substrates. For example, camera sensor 16 and image processing circuitry 14 may be formed on separate substrates that have been stacked.

Camera module 12 may convey acquired image data to host subsystems 19 over path 18 (e.g., image processing and data formatting circuitry 14 may convey image data to subsystems 19). Electronic device 10 typically provides a user with numerous high-level functions. In a computer or advanced cellular telephone, for example, a user may be provided with the ability to run user applications. To implement these functions, host subsystem 19 of electronic device 10 may include storage and processing circuitry 17 and input-output devices 21 such as keypads, input-output ports, joysticks, and displays. Storage and processing circuitry 17 may include volatile and nonvolatile memory (e.g., random-access memory, flash memory, hard drives, solid state drives, etc.). Storage and processing circuitry 17 may also include microprocessors, microcontrollers, digital signal processors, application specific integrated circuits, or other processing circuits.

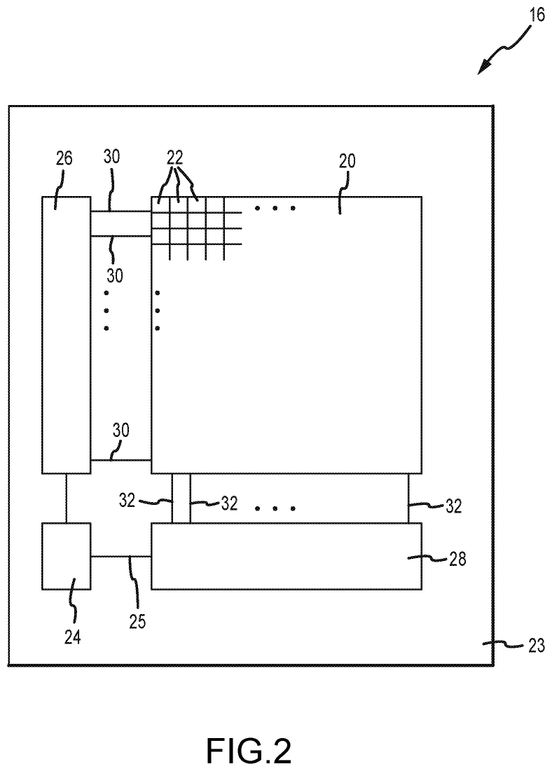

As shown in FIG. 2, image sensor 16 may include pixel array 20 containing image sensor pixels 22 arranged in rows and columns (sometimes referred to herein as image pixels or pixels) and control and processing circuitry 24 (which may include, for example, image signal processing circuitry). Array 20 may contain, for example, hundreds or thousands of rows and columns of image sensor pixels 22. Control circuitry 24 may be coupled to row control circuitry 26 and image readout circuitry 28 (sometimes referred to as column control circuitry, readout circuitry, processing circuitry, or column decoder circuitry). Pixel array 20, control and processing circuitry 24, row control circuitry 26, and image readout circuitry 28 may be formed on a substrate 23. If desired, some or all of the components of image sensor 16 may instead be formed on substrates other than substrate 23, which may be connected to substrate 23, for instance, through wire bonding or flip-chip bonding.

Row control circuitry 26 may receive row addresses from control circuitry 24 and supply corresponding row control signals such as reset, row-select, charge transfer, dual conversion gain, and readout control signals to pixels 22 over row control paths 30. One or more conductive lines such as column lines 32 may be coupled to each column of pixels 22 in array 20. Column lines 32 may be used for reading out image signals from pixels 22 and for supplying bias signals (e.g., bias currents or bias voltages) to pixels 22. If desired, during pixel readout operations, a pixel row in array 20 may be selected using row control circuitry 26 and image signals generated by image pixels 22 in that pixel row can be read out along column lines 32.

Image readout circuitry 28 may receive image signals (e.g., analog pixel values generated by pixels 22) over column lines 32. Image readout circuitry 28 may include sample-and-hold circuitry for sampling and temporarily storing image signals read out from array 20, amplifier circuitry, analog-to-digital conversion (ADC) circuitry, bias circuitry, column memory, latch circuitry for selectively enabling or disabling the column circuitry, or other circuitry that is coupled to one or more columns of pixels in array 20 for operating pixels 22 and for reading out image signals from pixels 22. ADC circuitry in readout circuitry 28 may convert analog pixel values received from array 20 into corresponding digital pixel values (sometimes referred to as digital image data or digital pixel data). Image readout circuitry 28 may supply digital pixel data to control and processing circuitry 24 over path 25 for pixels in one or more pixel columns.

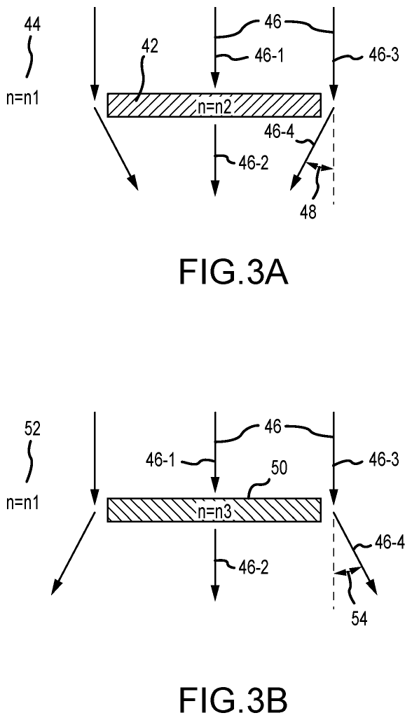

Each imaging pixel in the pixel array may include a microlens formed over a respective photodiode. Each photodiode may generate charge in response to incident light. However, in some cases a photodiode thickness may not be sufficient to have a satisfactory response to a desired wavelength of light. Light having longer wavelengths generally travels further (less absorption) within the photodiode before being converted to charge than light having smaller wavelengths (due to the absorption coefficient of light having longer wavelengths being lower than the absorption coefficient of light having shorter wavelengths). For example, near-infrared light (e.g., light having a wavelength between 700 nanometers and 1000 nanometers) may have lower than desired quantum efficiency. Quantum efficiency of light can be improved either by enhancing its absorption coefficient or increasing its effective path length within the photodiode. The lower than desired quantum efficiency may arise due to the effective path length of the near-infrared (NIR) light being too short. This means that some of the NIR light passes completely through the photodiode without being converted to charge, thus reducing efficiency. To increase the efficiency of a pixel's response to incident light of longer wavelengths such as NIR light, light spreading structures may be used. Light spreading structures may increase the effective path length of the incident light within the photodiode having a fixed thickness, allowing for improved efficiency without requiring the thickness of the photodiode to be increased. One type of light spreading structure that may be used is a diffractive lens. Diffractive lenses may also be used to focus light onto the photodiode before it is then spread by an additional diffractive lens. Examples of various types of focusing and defocusing diffractive lenses that may be used in imaging pixels are shown in FIGS. 3-5.

FIGS. 3A and 3B are cross-sectional side views of illustrative diffractive lenses that may be used in image sensors. As shown in FIG. 3A, a diffractive lens 42 may be formed in a surrounding medium 44. The surrounding material 44 may be formed from a first material that has a first index of refraction (n1). Diffractive lens 42 may be formed from a second material that has a second index of refraction (n2). In the example of FIG. 3A, the index of refraction of the lens may be greater than the index of refraction of the surrounding material (i.e., n2>n1). This results in incident light being focused towards a focal point. In this arrangement, diffractive lens 42 acts as a convex lens.

Lens 42 may be transparent to incident light. Therefore, some light may pass through the lens without being focused. For example, incident light 46-1 may pass through the center of diffractive lens 42. The corresponding light 46-2 on the other side of the diffractive lens may travel in the same direction as incident light 46-1. In contrast, incident light at the edge of diffractive lens 42 may be redirected due to diffraction. For example, incident light 46-3 may pass by the edge of diffractive lens 42. The light may be redirected such that the output light 46-4 travels at an angle 48 relative to the incident light 46-3. In other words, the diffractive lens redirects the light at the edge of the lens using diffraction.

Diffraction occurs when a wave (such as light) encounters an obstacle. When light passes around the edge of an object, it will be bent or redirected such that the direction of the original incident light changes. The amount and direction of bending depends on numerous factors. In an imaging sensor, diffraction of light can be used (with diffractive lenses) to redirect incident light in desired ways (i.e., focusing incident light on photodiodes to mitigate optical cross-talk).

In the example of FIG. 3A, diffractive lens 42 has an index of refraction greater than the index of refraction of the surrounding medium 44. This causes incident light to be focused towards a focal point. However, this example is merely illustrative and other embodiments may be used.

As shown in FIG. 3B, a diffractive lens 50 may be formed in a surrounding medium 52. The surrounding material 52 may be formed from a first material that has a first index of refraction (n1). Diffractive lens 50 may be formed from a third material that has a third index of refraction (n3). In the example of FIG. 3B, the index of refraction of the lens may be less than the index of refraction of the surrounding material (i.e., n1>n3). This results in incident light 46 being defocused. In this arrangement, diffractive lens 50 acts as a concave lens.

Lens 50 may be transparent to incident light. Therefore, some light may pass through the lens without being focused. For example, incident light 46-1 may pass through the center of diffractive lens 50. The corresponding light 46-2 on the other side of the diffractive lens may travel in the same direction as incident light 46-1. In contrast, incident light at the edge of diffractive lens 50 may be redirected due to diffraction. For example, incident light 46-3 may pass by the edge of diffractive lens 50. The light may be redirected such that the output light 46-4 travels at an angle 54 relative to the incident light 46-3. In other words, the diffractive lens redirects the light at the edge of the lens using diffraction.

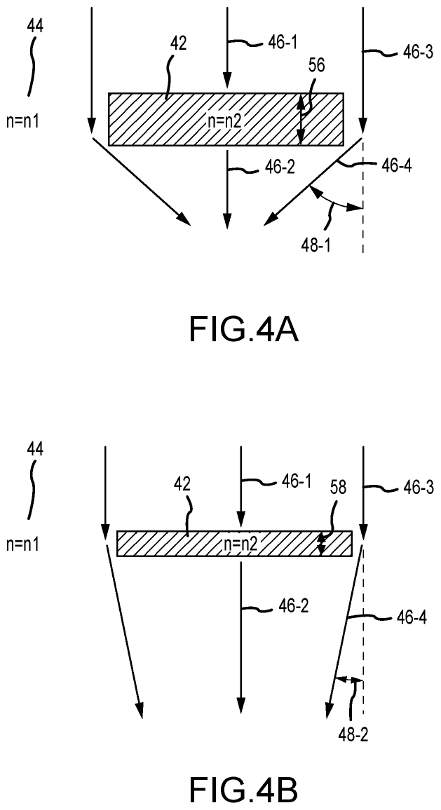

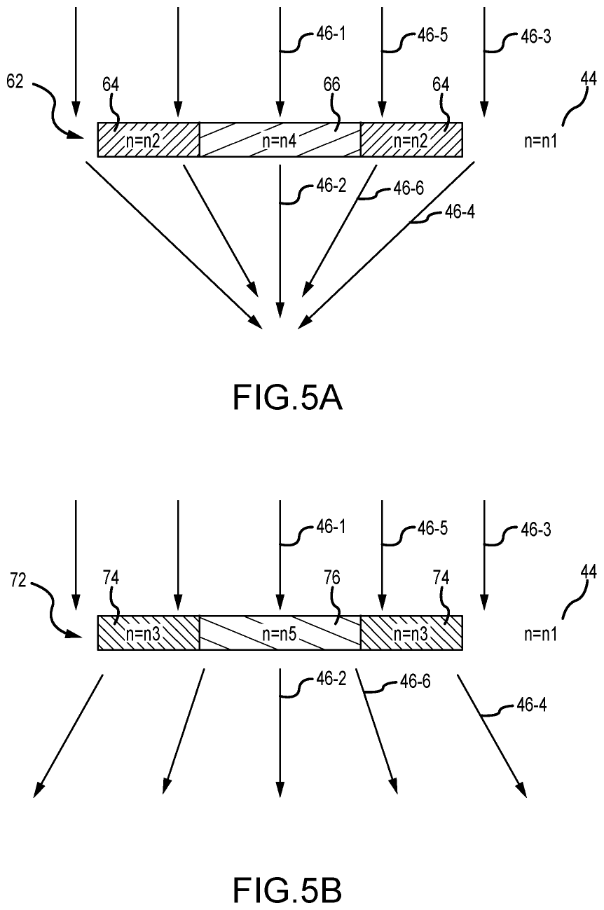

In addition to the refractive indices of the diffractive lens and the surrounding material, the thickness of the diffractive lens may also affect the response of incident light to the diffractive lens. FIGS. 4A and 4B show illustrative diffractive lenses used to focus incident light (as in FIG. 3A, for example). As shown in FIG. 4A, a diffractive lens 42 may be formed in a surrounding medium 44. The surrounding material 44 may be formed from a first material that has a first index of refraction (n1). Diffractive lens 42 may be formed from a second material that has a second index of refraction (n2). In the example of FIG. 4A, the index of refraction of the lens may be greater than the index of refraction of the surrounding material (i.e., n2>n1). This results in the light being focused to a focal point.

In particular, incident light 46-3 may pass by the edge of diffractive lens 42. The light may be redirected such that the output light 46-4 travels at an angle 48-1 relative to the incident light 46-3. This angle may be dependent upon the thickness 56 of diffractive lens 42. In the example of FIG. 4A, thickness 56 is associated with an angle of diffraction of 48-1. Diffractive lens 42 in FIG. 4A may have a relatively large thickness and, accordingly, a relatively large angle of diffraction 48-1.

In contrast, diffractive lens 42 in FIG. 4B may have a relatively small thickness and a relatively small angle of diffraction 48-2. As shown in FIG. 4B, a diffractive lens 42 may be formed in a surrounding medium 44. The surrounding material 44 may be formed from a first material that has a first index of refraction (n1). Diffractive lens 42 may be formed from a second material that has a second index of refraction (n2). In the example of FIG. 4B, the index of refraction of the lens may be greater than the index of refraction of the surrounding material (i.e., n2>n1). This results in the light being focused to a focal point. In particular, the light at the edge of the diffractive lens may be redirected such that the output light 46-4 travels at an angle 48-2 relative to the incident light 46-3. This angle may be dependent upon the thickness 58 of diffractive lens 42. Because thickness 58 in FIG. 4B is less than thickness 56 in FIG. 4A, angle 48-2 in FIG. 4B is less than angle 48-1 in FIG. 4A.

Diffractive lenses 42 in FIGS. 4A and 4B have the same length and width. However, the length and width of diffractive lenses may also be adjusted to alter the response of incident light 46. The diffractive lenses may only redirect incident light that passes within a given distance of the edge of the diffractive lens (e.g., the interface between the two materials having different indices of refraction). The given distance may be approximately one half of the wavelength of the incident light.

This shows how diffractive lenses may be used to redirect incident light in desired ways. The refractive indices of the lens and surrounding material may be altered to customize the response of incident light. Additionally, the thickness, length, and width, of the diffractive lens may be altered to customize the response of incident light.

In FIGS. 3A, 3B, 4A, and 4B, diffractive lenses (e.g., diffractive lens 42 and diffractive lens 50) are depicted as being formed from a single layer of material having a first index of refraction that is surrounded by a surrounding medium having a second index of refraction that is different than the first index of refraction. Because these diffractive lenses have one uniform index of refraction (and therefore one refractive index difference between the lens and surrounding medium), these types of diffractive lenses may be referred to as single-edge diffractive lenses. These types of diffractive lenses may also be referred to as single-refractive-index diffractive lenses.

The aforementioned single-edge diffractive lenses may be effective at focusing or defocusing light at the edges of the diffractive lens. Light at the center of the diffractive lenses may pass through without being focused or defocused as desired. However, light between the center and edges of the diffractive lenses passes through the diffractive lens without being focused or defocused. This may not be desirable, as performance of the lens may be improved if light between the center and edges of the diffractive lens was also focused or defocused.

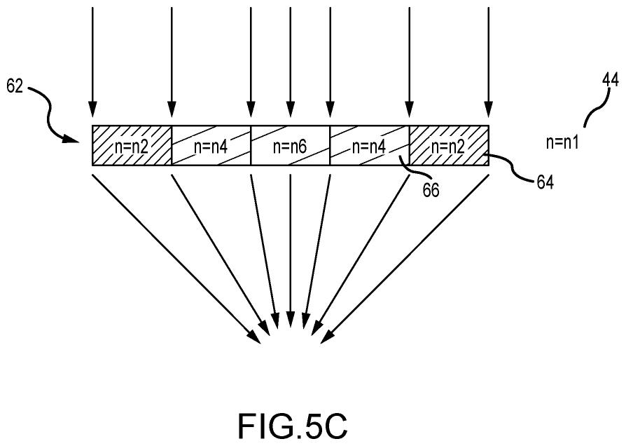

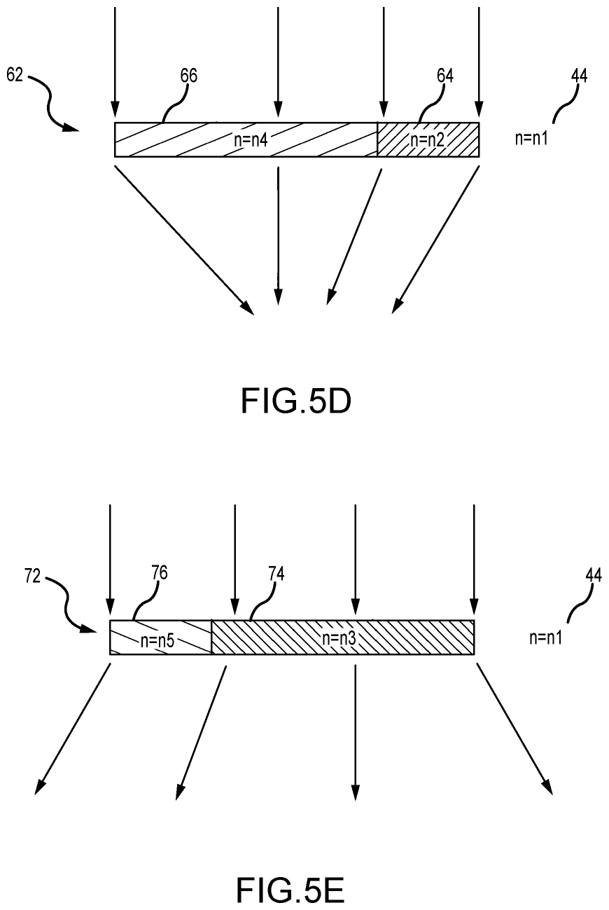

To better focus light, a diffractive lens may therefore have two or more portions with different refractive indices. Examples of this type are shown in FIGS. 5A and 5B.

As shown in FIG. 5A, a diffractive lens 62 may be formed in a surrounding medium 44. The surrounding material 44 may be formed from a first material that has a first index of refraction (n1). Diffractive lens 62 may have first portions 64 formed from a second material that has a second index of refraction (n2) and a second portion 66 formed from a third material that has a third index of refraction (n4). In the example of FIG. 5A, the index of refraction of the second portion of the lens (n4) may be greater than the index of refraction of the first portion of the lens (n2) and the index of refraction of the first portion of the lens may be greater than the index of refraction of the surrounding material (i.e., n4>n2>n1). This results in incident light being focused towards a focal point. In this arrangement, diffractive lens 62 acts as a convex lens.

Lens 62 (i.e., both portions 64 and 66 of lens 62) may be transparent to incident light. Therefore, some light may pass through the lens without being focused. For example, incident light 46-1 may pass through the center of portion 66 of diffractive lens 62. The corresponding light 46-2 on the other side of the diffractive lens may travel in the same direction as incident light 46-1. In contrast, incident light at the edge of diffractive lens 62 may be redirected due to diffraction. For example, incident light 46-3 may pass by the edge of diffractive lens 62. The light may be redirected such that the output light 46-4 travels at an angle relative to the incident light 46-3. In other words, the diffractive lens redirects the light at the edge of the lens using diffraction. Additionally, due to the additional refractive index difference between portions 64 and 66 of the diffractive lens, light between the edge and center of the diffractive lens may also be redirected. For example, incident light 46-5 may pass by the interface of portions 64 and 66 of diffractive lens 62. The light may be redirected such that the output light 46-6 travels at an angle relative to the incident light 46-5.

The difference in refractive index between each material may be any desired refractive index difference (e.g., greater than 0.2, greater than 0.3, greater than 0.4, greater than 0.5, greater than 0.8, greater than 1.0, between 0.2 and 0.5, between 0.2 and 0.8, between 0.2 and 1.0, less than 1.0, less than 0.5, less than 0.3, etc.).

The example of the diffractive lens having two portions in FIG. 5A is merely illustrative. If desired, the diffractive lens may have three portions having different refractive indices (as will be shown in FIG. 5C), four portions having different refractive indices, five portions having different refractive indices, more than five portions having different refractive indices, etc. Regardless of how many portions are present in the diffractive lens, each pair of adjacent portions may have a corresponding refractive index difference. For example, the refractive index of each portion may increase proportionally with the distance of the portion from the edge (meaning that an edge portion such as portion 64 has a lower refractive index than a center portion such as portion 66). Said another way, the refractive index of each portion may decrease proportionally with the distance of the portion from the center.

In the example of FIG. 5A, diffractive lens 62 causes incident light to be focused towards a focal point. However, this example is merely illustrative and other embodiments may be used. FIG. 5B shows a diffractive lens with two or more portions having different refractive indices that defocuses light.

As shown in FIG. 5B, a diffractive lens 72 may be formed in a surrounding medium 44. The surrounding material 44 may be formed from a first material that has a first index of refraction (n1). Diffractive lens 72 may have first portions 74 formed from a second material that has a second index of refraction (n3) and a second portion 76 formed from a third material that has a third index of refraction (n5). In the example of FIG. 5B, the index of refraction of the second portion of the lens (n5) may be less than the index of refraction of the first portion of the lens (n3) and the index of refraction of the first portion of the lens (n3) may be less than the index of refraction of the surrounding material (i.e., n5<n3<n1). This results in incident light being defocused. In this arrangement, diffractive lens 72 acts as a concave lens.

Lens 72 (i.e., both portions 74 and 76 of lens 72) may be transparent to incident light. Therefore, some light may pass through the lens without being focused. For example, incident light 46-1 may pass through the center of portion 76 of diffractive lens 72. The corresponding light 46-2 on the other side of the diffractive lens may travel in the same direction as incident light 46-1. In contrast, incident light at the edge of diffractive lens 72 may be redirected due to diffraction. For example, incident light 46-3 may pass by the edge of diffractive lens 72. The light may be redirected such that the output light 46-4 travels at an angle relative to the incident light 46-3. In other words, the diffractive lens redirects the light at the edge of the lens using diffraction. Additionally, due to the additional refractive index difference between portions 74 and 76 of the diffractive lens, light between the edge and center of the diffractive lens may also be redirected. For example, incident light 46-5 may pass by the interface of portions 74 and 76 of diffractive lens 72. The light may be redirected such that the output light 46-6 travels at an angle relative to the incident light 46-5.

The difference in refractive index between each material may be any desired refractive index difference (e.g., greater than 0.2, greater than 0.3, greater than 0.4, greater than 0.5, greater than 0.8, greater than 1.0, between 0.2 and 0.5, between 0.2 and 0.8, between 0.2 and 1.0, less than 1.0, less than 0.5, less than 0.3, etc.).

The example of the diffractive lens having two portions in FIG. 5B is merely illustrative. If desired, the diffractive lens may have three portions having different refractive indices, four portions having different refractive indices, five portions having different refractive indices, more than five portions having different refractive indices, etc. Each pair of adjacent portions may have a corresponding refractive index difference. For example, the refractive index of each portion may decrease proportionally with the distance of the portion from the edge (meaning that an edge portion such as portion 64 has a higher refractive index than a center portion such as portion 66). Said another way, the refractive index of each portion may increase proportionally with the distance of the portion from the center.

FIG. 5C is a cross-sectional side view of an illustrative diffractive lens with more than two portions. As shown in FIG. 5C, a focusing diffractive lens 62 may be formed in a surrounding medium 44. The surrounding material 44 may be formed from a first material that has a first index of refraction (n1). Diffractive lens 62 may have first portions 64 formed from a second material that has a second index of refraction (n2), a second portion 66 formed from a third material that has a third index of refraction (n4), and a third portion 68 formed from a fourth material that has a fourth index of refraction (n6). In the example of FIG. 5C, the index of refraction of the third portion of the lens (n6) may be greater than the index of refraction of the second portion of the lens (n4), the index of refraction of the second portion of the lens (n4) may be greater than the index of refraction of the first portion of the lens (n2), and the index of refraction of the first portion of the lens may be greater than the index of refraction of the surrounding material (i.e., n6>n4>n2>n1). This results in incident light being focused towards a focal point. In this arrangement, diffractive lens 62 acts as a convex lens. The portions of the diffractive lens in FIG. 5C may be concentric (i.e., all of the portions share a common geometrical center).

In the examples of FIGS. 5A-5C, symmetrical diffractive lenses with two or more portions are shown. However, the diffractive lenses do not need to be symmetrical. The diffractive lens may instead be asymmetric to control the focusing/defocusing of the light in any desired manner. The diffractive lenses may be asymmetrical as shown in FIGS. 5D and 5E. As shown in FIG. 5D, a diffractive lens 62 may be formed in a surrounding medium 44. The surrounding material 44 may be formed from a first material that has a first index of refraction (n1). Diffractive lens 62 may have a first portion 64 formed from a second material that has a second index of refraction (n2) and a second portion 66 formed from a third material that has a third index of refraction (n4). In the example of FIG. 5A, the index of refraction of the second portion of the lens (n4) may be greater than the index of refraction of the first portion of the lens (n2) and the index of refraction of the first portion of the lens may be greater than the index of refraction of the surrounding material (i.e., n4>n2>n1). This results in incident light being focused towards a focal point. In this arrangement, diffractive lens 62 acts as a convex lens. Because the diffractive lens is asymmetric, the focal point may not be centered underneath the diffractive lens.

The difference in refractive index between each material may be any desired refractive index difference (e.g., greater than 0.2, greater than 0.3, greater than 0.4, greater than 0.5, greater than 0.8, greater than 1.0, between 0.2 and 0.5, between 0.2 and 0.8, between 0.2 and 1.0, less than 1.0, less than 0.5, less than 0.3, etc.).

The example of the diffractive lens having two portions in FIG. 5D is merely illustrative. If desired, the asymmetric diffractive lens may have three portions having different refractive indices, four portions having different refractive indices, five portions having different refractive indices, more than five portions having different refractive indices, etc. Regardless of how many portions are present in the diffractive lens, each pair of adjacent portions may have a corresponding refractive index difference.

The asymmetric diffractive lens may instead be a defocusing diffractive lens. As shown in FIG. 5E, a diffractive lens 72 may be formed in a surrounding medium 44. The surrounding material 44 may be formed from a first material that has a first index of refraction (n1). Diffractive lens 72 may have a first portion 74 formed from a second material that has a second index of refraction (n3) and a second portion 76 formed from a third material that has a third index of refraction (n5). In the example of FIG. 5E, the index of refraction of the second portion of the lens (n5) may be less than the index of refraction of the first portion of the lens (n3) and the index of refraction of the first portion of the lens (n3) may be less than the index of refraction of the surrounding material (i.e., n5<n3<n1). This results in incident light being defocused. However, the defocusing is asymmetric due to the asymmetric structure of diffractive lens 72. In this arrangement, diffractive lens 72 acts as a concave lens.

The difference in refractive index between each material may be any desired refractive index difference (e.g., greater than 0.2, greater than 0.3, greater than 0.4, greater than 0.5, greater than 0.8, greater than 1.0, between 0.2 and 0.5, between 0.2 and 0.8, between 0.2 and 1.0, less than 1.0, less than 0.5, less than 0.3, etc.).

The example of the diffractive lens having two portions in FIG. 5E is merely illustrative. If desired, the asymmetric defocusing diffractive lens may have three portions having different refractive indices, four portions having different refractive indices, five portions having different refractive indices, more than five portions having different refractive indices, etc. Regardless of how many portions are present in the diffractive lens, each pair of adjacent portions may have a corresponding refractive index difference.

The diffractive lenses of FIGS. 5A-5E each have two or more portions with different refractive indices. The diffractive lenses may therefore be referred to as multiple-refractive-index diffractive lenses. The diffractive lenses of FIGS. 5A-5E also form multiple refractive index differences. For example, in FIG. 5A, the interface between portions 64 and surrounding material 44 is a first refractive index difference and the interface between portions 64 and portion 66 is a second refractive index difference. In FIG. 5B, the interface between portions 74 and surrounding material 44 is a first refractive index difference and the interface between portions 74 and portion 76 is a second refractive index difference. The lenses of FIG. 5A-5E may therefore sometimes be referred to as multiple-edge diffractive lenses, multiple-portioned diffractive lenses, compound diffractive lenses, composite diffractive lenses, multipart diffractive lenses, etc.

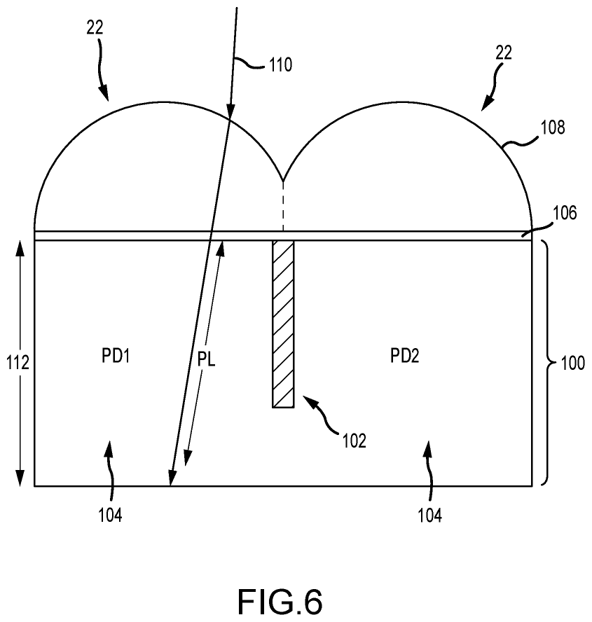

A cross-sectional side view of an image sensor without diffractive lenses to increase path length is shown in FIG. 6. As shown, the image sensor may include pixels 22 that each include a respective photodiode 104 formed in substrate 100 (e.g., a semiconductor substrate such as silicon). FIG. 6 shows a first pixel that has photodiode PD1 and a second photodiode that has photodiode PD2.

Isolation structures 102 may be formed between each adjacent pair of photodiodes in the image sensor. Isolation structures 102 may be any desired type of isolation structure. For example, the isolation structures may be formed by a doped portion of semiconductor substrate 100. The photodiodes 104 may be formed from an n-type doped portion of substrate 100 and isolation structures 102 may be formed from a p-type doped portion of substrate 100, for example. Isolation structures 102 may be formed from shallow trench isolation (STI) or deep trench isolation (DTI). FIG. 6 shows an example where the isolation structures are formed from deep trench isolation. The deep trench isolation may include a material (a dielectric material such as silicon dioxide or silicon nitride or a conductive material such as tungsten) formed in a trench in the substrate between adjacent photodiodes. Isolation structure 102 may be opaque to incident light, thereby preventing cross-talk between adjacent pixels. Light may reflect off of the isolation structures so that it can later be detected by the photodiode.

As shown in FIG. 6, a passivation layer(s) 106 (sometimes referred to as a planarization layer, dielectric layer, etc.) may be formed over the substrate. The passivation layer may be formed from silicon dioxide or silicon nitride, for example. A single passivation layer may be formed over the substrate or multiple passivation layers may be formed over the substrate. The passivation layer may be covered by additional films such as a clear film or color filter array (CFA) and microlenses 108 or by microlenses only. Each photodiode may be covered by a respective microlens. Each microlens 108 may have a curved upper surface that is configured to focus light onto the underlying photodiode using refraction.

The image sensor of FIG. 6 does not include diffractive lenses. The path length of incident light may therefore be shorter than desired. Consider, for example, incident light 110 in FIG. 6. When incident light 110 reaches microlens 108, the microlens focuses the light towards photodiode PD1. The incident light then passes directly through substrate 100. The length of the path that the incident light travels within the substrate may be referred to as path length. In general, the longer the path length for incident light, the more likely the light will be converted to charge by the photodiode. Therefore, to increase efficiency in the image sensor, it is desirable for incident light to have an average path length sufficiently long to be absorbed by the photodiode. In FIG. 6, the incident light has a path length PL. Without any diffractive lenses for spreading the light, the path length in FIG. 6 is similar to the thickness 112 of the semiconductor substrate. To increase the path length of incident light, light spreading structures may be incorporated into the image sensor.

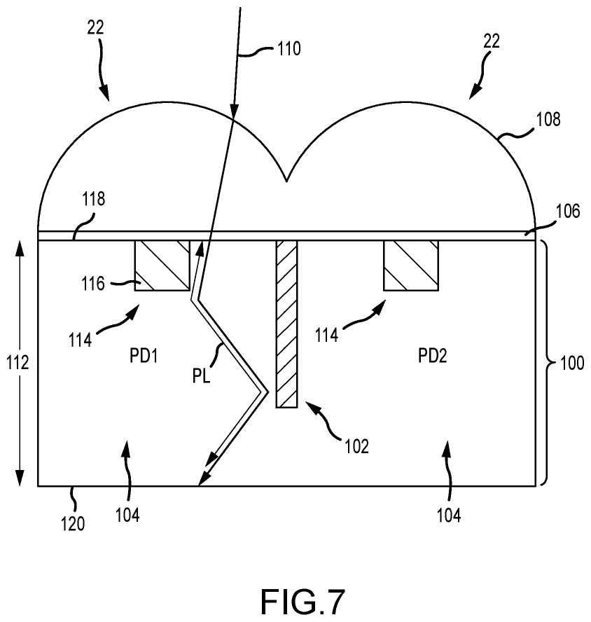

FIG. 7 is a cross-sectional side view of an image sensor with light spreading structures. As shown in FIG. 7, similar to as in FIG. 6 the image sensor includes pixels 22 that each have a photodiode 104 covered by a microlens 108. An isolation structure 102 is interposed between each adjacent pair of photodiodes. A passivation layer 106 is formed over the photodiodes.

The imaging pixels in FIG. 7 also include light spreading structures 114. The light spreading structures 114 herein are diffractive lenses (though it should be understood that other types of light spreading structures may be used) and therefore may sometimes be referred to as diffractive lenses 114. In FIG. 7, light spreading structure 114 includes a first diffractive lens 116 formed in semiconductor substrate 100. The diffractive lens may be formed from a material that has an index of refraction that is lower than the index of refraction of the surrounding semiconductor substrate. Accordingly, diffractive lens 116 serves as a defocusing lens that spreads light (similar to as shown in FIG. 3B, for example).

Incident light 110 is focused towards photodiode PD1 by microlens 108. The incident light is then redirected by diffractive lens 116. The incident light may be spread by the defocusing diffractive lens and redirected towards isolation structure 102, for example. The light may reflect off of isolation structure 102 and pass through the remaining portion of photodiode PD1. Because the light is redirected (spread) by diffractive lens 116, incident light 110 has a corresponding path length PL that is longer than the path length of FIG. 6 (when diffractive lens 116 is not present). In general, the presence of diffractive lens 116 causes incident light to be spread, which increases the average path length of the incident light. This increase in average path length improves the efficiency of the pixel (because the light is more likely to be absorbed by the photodiode) without increasing the thickness 112 of substrate 100.

Diffractive lens 116 may be formed from any desired material. For example, the diffractive lens may be formed from a dielectric material such as silicon dioxide or silicon nitride. The diffractive lens may optionally be formed from the same material as passivation layer 106. In these embodiments, the passivation layer may be considered to have a passivation portion with a first thickness and a diffractive lens portion with a second thickness that is greater than the first thickness.

The diffractive lens may be formed in a trench within substrate 100. The substrate 100 may be formed from a semiconductor material such as silicon and may have a front surface 120 (sometimes referred to front side surface or front side) and a back surface 118 (sometimes referred to as backside surface of back side). A trench may be formed in backside surface 118. The trench may be extended partially through the thickness of the photodiode or through the full thickness of the photodiode. The material that forms diffractive lens 116 may fill the trench. The material deposited in the trench may have a lower index of refraction than the surrounding silicon substrate. The diffractive lens may be described as being formed in the photodiode. The photodiode may completely laterally surround the diffractive lens.

The difference in refractive index between the diffractive lens and the semiconductor substrate 100 may be any desired refractive index difference (e.g., greater than 0.2, greater than 0.3, greater than 0.4, greater than 0.5, greater than 0.8, greater than 1.0, greater than 1.2, greater than 1.4, greater than 1.6, between 0.2 and 0.5, between 0.2 and 0.8, between 0.2 and 1.8, less than 2.0, less than 1.0, less than 0.3, etc.).

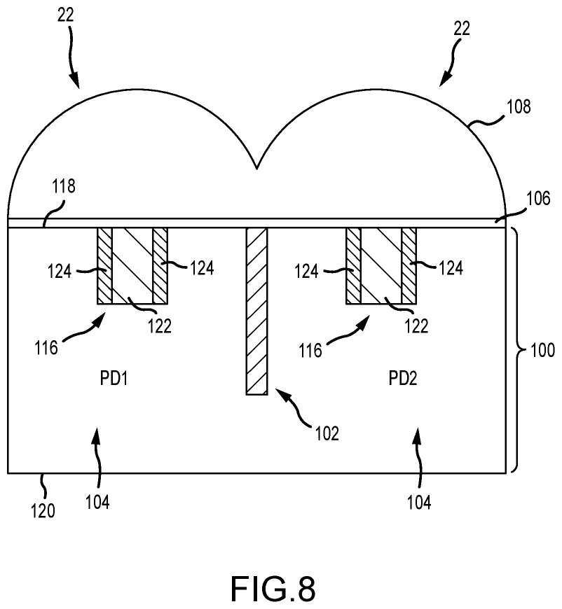

FIG. 7 shows an example where a single-edge diffractive lens is formed in semiconductor substrate 100. However, this example is merely illustrative. If desired, as shown in FIG. 8, a multiple-edge diffractive lens may be formed in semiconductor substrate 100.

FIG. 8 is a cross-sectional side view of an image sensor where each imaging pixel has a respective multiple-edge diffractive lens to spread incident light and increase the path length of incident light. The multiple-edge diffractive lens 116 includes a first portion 122 with a first refractive index. The first portion 122 of the multiple-edge diffractive lens 116 is surrounded by second portions 124 that have a second refractive index that is greater than the first refractive index. The second refractive index is also lower than the refractive index (e.g., a third refractive index) of the surrounding semiconductor substrate. This arrangement for a multiple-edge diffractive lens (which is similar to the arrangement of FIG. 5B) causes defocusing of the incident light, which increases the average path length of the incident light within the photodiode.

Each portion of multiple-edge diffractive lens 116 may be formed from any desired material having any desired refractive index. For example, portion 122 may be formed from silicon dioxide and portions 124 may be formed from silicon nitride. The difference in refractive index between the first and second diffractive lens portions may be any desired refractive index difference (e.g., greater than 0.2, greater than 0.3, greater than 0.4, greater than 0.5, greater than 0.8, greater than 1.0, greater than 1.2, greater than 1.4, greater than 1.6, between 0.2 and 0.5, between 0.2 and 0.8, between 0.2 and 1.8, less than 2.0, less than 1.0, less than 0.3, etc.). The difference in refractive index between the second diffractive lens portions 124 and the semiconductor substrate 100 may be any desired refractive index difference (e.g., greater than 0.2, greater than 0.3, greater than 0.4, greater than 0.5, greater than 0.8, greater than 1.0, greater than 1.2, greater than 1.4, greater than 1.6, between 0.2 and 0.5, between 0.2 and 0.8, between 0.2 and 1.8, less than 2.0, less than 1.0, less than 0.3, etc.).

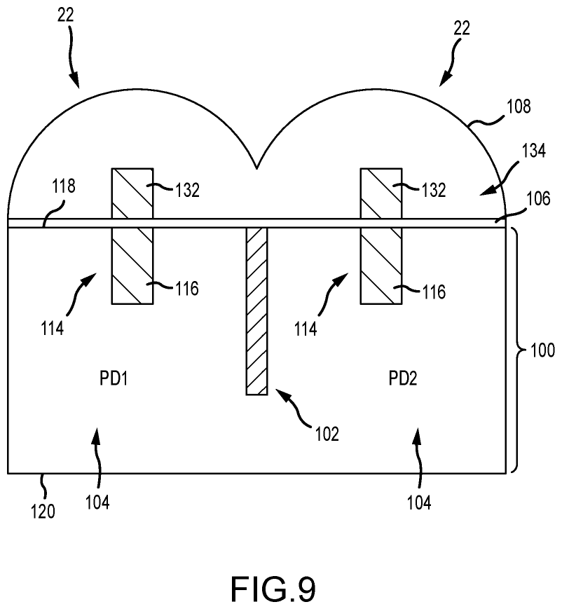

In FIGS. 7 and 8, the light spreading structures include a diffractive lens in the semiconductor substrate of each imaging pixel. However, the light spreading structures may include structures in other positions within the imaging pixels. For example, in addition to the diffractive lens formed in the semiconductor substrate, a diffractive lens may be formed above the semiconductor substrate, as shown in FIGS. 9-11.

FIG. 9 is a cross-sectional side view of an image sensor with light spreading structures. As shown in FIG. 9, the image sensor includes pixels 22 that each have a photodiode 104 covered by a thin film such as a clear film or color filter array and a microlens 108. An isolation structure 102 is interposed between each adjacent pair of photodiodes. A passivation layer 106 is formed over the photodiodes and may also be formed between diffractive lenses 116 and the photodiodes.

The imaging pixels in FIG. 9 also include light spreading structures 114. The light spreading structures 114 herein are diffractive lenses and therefore may sometimes be referred to as diffractive lenses 114. In FIG. 9, light spreading structure 114 includes a first diffractive lens 116 formed in semiconductor substrate 100 and a second diffractive lens 132 formed over semiconductor substrate 100.

Diffractive lens 116 may be formed from a material that has an index of refraction that is lower than the index of refraction of the surrounding semiconductor substrate. Accordingly, diffractive lens 116 serves as a defocusing lens that spreads light (similar to as shown in FIG. 3B, for example). Diffractive lens 132 may be formed from a material that has an index of refraction that is higher than the index of refraction of the surrounding material. Accordingly, diffractive lens 132 serves as a focusing lens that focuses light (similar to as shown in FIG. 3A, for example). Diffractive lens 132 may be surrounded by passivation layers, material used to form microlenses 108, material used to form a color filter element, air, and/or or any other desired material.

Incorporating diffractive lens 132 over diffractive lens 116 may focus incident light onto diffractive lens 116. By focusing more light onto diffractive lens 116, more of the incident light may be spread by diffractive lens 116. Therefore, even though diffractive lens 132 serves to focus light, diffractive lens 132 ultimately improves the light spreading within the pixel. Diffractive lenses 116 and 132 may therefore both be referred to as light spreading structures 114.

Diffractive lens 116 may be formed from any desired material. For example, the diffractive lens may be formed from a dielectric material such as silicon dioxide or silicon nitride. The diffractive lens may optionally be formed from the same material as passivation layer 106. In these embodiments, the passivation layer may be considered to have a passivation portion with a first thickness and a diffractive lens portion with a second thickness that is greater than the first thickness.

Diffractive lens 132 may be formed from any desired material. For example, the diffractive lens may be formed from a dielectric material such as silicon dioxide or silicon nitride. The diffractive lens may optionally be formed from the same material as passivation layer 106. Diffractive lens 132 may optionally be formed from the same material as diffractive lens 116.

Diffractive lens 116 may be formed in a trench in back surface 118 of substrate 100. Edge surfaces of diffractive lens 116 may directly contact the silicon that forms substrate 100. Alternatively, a passivation layer may be formed between the photodiode and diffractive lens 116. The passivation layer may have a first side that directly contacts the photodiode and a second side that directly contacts the diffractive lens. In contrast, diffractive lens 132 may be formed over the back surface 118 of substrate 100. Edge surface of diffractive lens 132 may directly contact passivation layers, material used to form microlenses 108, material used to form a color filter element, air, or any other desired material. The material surrounding diffractive lens 132 (e.g., material 134) may sometimes be referred to as a cladding or dielectric material.

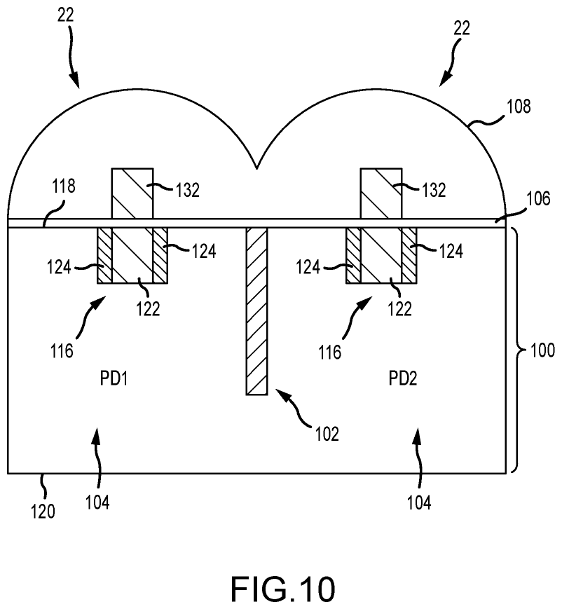

The difference in refractive index between diffractive lens 116 and the semiconductor substrate 100 may be any desired refractive index difference (e.g., greater than 0.2, greater than 0.3, greater than 0.4, greater than 0.5, greater than 0.8, greater than 1.0, greater than 1.2, greater than 1.4, greater than 1.6, between 0.2 and 0.5, between 0.2 and 0.8, between 0.2 and 1.8, less than 2.0, less than 1.0, less than 0.3, etc.). The difference in refractive index between diffractive lens 132 and surrounding material 134 may be any desired refractive index difference (e.g., greater than 0.2, greater than 0.3, greater than 0.4, greater than 0.5, greater than 0.8, greater than 1.0, between 0.2 and 0.5, between 0.2 and 0.8, between 0.2 and 1.0, less than 1.0, less than 0.5, less than 0.3, etc.). Diffractive lens 116 and/or diffractive lens 132 may be multiple-edge diffractive lenses if desired. FIG. 10 is a cross-sectional side view of an illustrative image sensor with imaging pixels that have a multiple-edge diffractive lens in a semiconductor substrate and a single-edge diffractive lens above the semiconductor substrate. The multiple-edge diffractive lens 116 includes a first portion 122 with a first refractive index. The first portion 122 of the multiple-edge diffractive lens 116 is surrounded by second portions 124 that have a second refractive index that is greater than the first refractive index. The second refractive index is also lower than the refractive index (e.g., a third refractive index) of the surrounding semiconductor substrate. This arrangement for a multiple-edge diffractive lens (which is similar to the arrangement of FIG. 5B) causes defocusing of the incident light, which increases the average path length of the incident light within the photodiode.

Each portion of multiple-edge diffractive lens 116 may be formed from any desired material having any desired refractive index. For example, portion 122 may be formed from silicon dioxide and portions 124 may be formed from silicon nitride. Passivation layer 106 may be formed from the same material as portion 122 or portion 124 of diffractive lens 116. Diffractive lens 132 may be formed from any desired material. For example, the diffractive lens may be formed from a dielectric material such as silicon dioxide or silicon nitride. The diffractive lens may optionally be formed from the same material as passivation layer 106. Diffractive lens 132 may optionally be formed from the same material as portion 122 of diffractive lens 116. Diffractive lens 132 may optionally be formed from the same material as portions 124 of diffractive lens 116.

The difference in refractive index between the first and second diffractive lens portions 122 and 124 may be any desired refractive index difference (e.g., greater than 0.2, greater than 0.3, greater than 0.4, greater than 0.5, greater than 0.8, greater than 1.0, greater than 1.2, greater than 1.4, greater than 1.6, between 0.2 and 0.5, between 0.2 and 0.8, between 0.2 and 1.8, less than 2.0, less than 1.0, less than 0.3, etc.). The difference in refractive index between the second diffractive lens portions 124 and the semiconductor substrate 100 may be any desired refractive index difference (e.g., greater than 0.2, greater than 0.3, greater than 0.4, greater than 0.5, greater than 0.8, greater than 1.0, greater than 1.2, greater than 1.4, greater than 1.6, between 0.2 and 0.5, between 0.2 and 0.8, between 0.2 and 1.8, less than 2.0, less than 1.0, less than 0.3, etc.).

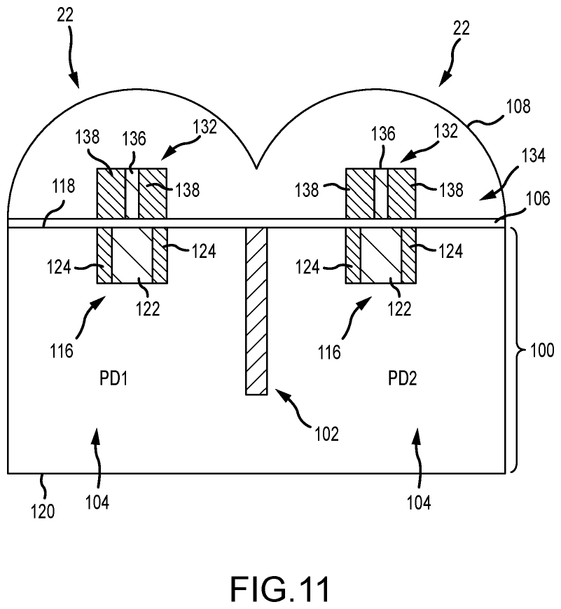

FIG. 11 is a cross-sectional side view of an illustrative image sensor with imaging pixels that have a multiple-edge diffractive lens in a semiconductor substrate and a multiple-edge diffractive lens above the semiconductor substrate. The image sensor of FIG. 11 is the same as the image sensor of FIG. 10, except for diffractive lens 132 being a multiple-edge diffractive lens instead of a single-edge diffractive lens.

As shown in FIG. 11, the multiple-edge diffractive lens 132 includes a first portion 136 with a first refractive index. The first portion 136 of the multiple-edge diffractive lens 132 is surrounded by second portions 138 that have a second refractive index that is less than the first refractive index. The second refractive index is also greater than the refractive index (e.g., a third refractive index) of the surrounding material 134. This arrangement for a multiple-edge diffractive lens (which is similar to the arrangement of FIG. 5A) causes focusing of the incident light onto diffractive lens 116, which increases the average path length of the incident light within the photodiode.

Each portion of multiple-edge diffractive lens 132 may be formed from any desired material having any desired refractive index. For example, portion 136 may be formed from silicon nitride and portions 138 may be formed from silicon dioxide. The difference in refractive index between the first and second diffractive lens portions may be any desired refractive index difference (e.g., greater than 0.2, greater than 0.3, greater than 0.4, greater than 0.5, greater than 0.8, greater than 1.0, greater than 1.2, greater than 1.4, greater than 1.6, between 0.2 and 0.5, between 0.2 and 0.8, between 0.2 and 1.8, less than 2.0, less than 1.0, less than 0.3, etc.). The difference in refractive index between the second diffractive lens portions 138 and the surrounding material 134 may be any desired refractive index difference (e.g., greater than 0.2, greater than 0.3, greater than 0.4, greater than 0.5, greater than 0.8, greater than 1.0, greater than 1.2, greater than 1.4, greater than 1.6, between 0.2 and 0.5, between 0.2 and 0.8, between 0.2 and 1.8, less than 2.0, less than 1.0, less than 0.3, etc.).

Portion 136 of diffractive lens 132 may be formed from the same material as portion 122 of diffractive lens 116, portion 124 of diffractive lens 116, and/or passivation layer 106. Portions 138 of diffractive lens 132 may be formed from the same material as portion 122 of diffractive lens 116, portion 124 of diffractive lens 116, and/or passivation layer 106.

In each of the image sensors depicted in FIGS. 7-11, a single diffractive lens (or pair of diffractive lenses) is included in each imaging pixel. This example is merely illustrative. To increase the amount of light spreading (and, correspondingly, the quantum efficiency of the pixels), multiple diffractive lenses (or multiple pairs of diffractive lenses) may be included in each imaging pixel.

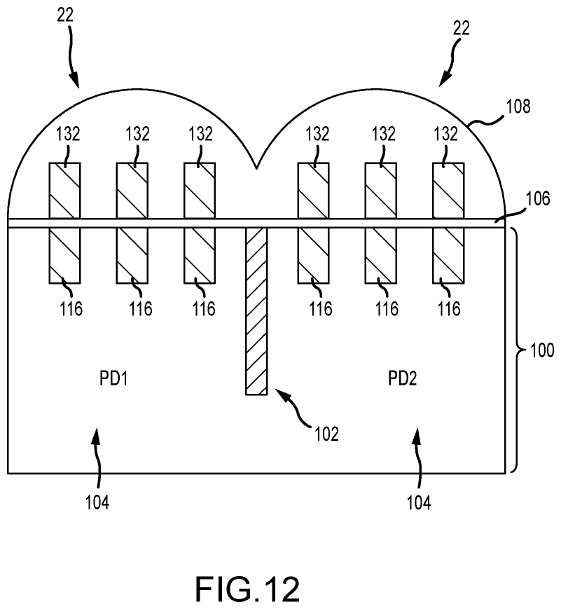

FIG. 12 is a cross-sectional side view of an illustrative image sensor with imaging pixels 22 that each include multiple diffractive lenses 116 in semiconductor substrate 100. In FIG. 12, each diffractive lens 116 in the semiconductor substrate is covered by a corresponding diffractive lens 132. Any desired number of diffractive lenses may be included in each imaging pixel.

The examples of diffractive lenses shown in FIGS. 7-12 are merely illustrative. In general, each diffractive lens depicted may be a diffractive lens of any desired type. For example, each diffractive lens may be a single-edge diffractive lens, may be a multiple-edge diffractive lens, may be an asymmetric diffractive lens (as in FIG. 5D or FIG. 5E, for example), etc. Each diffractive lens may be formed from any desired material having any desired refractive index.

Each diffractive lens may have any desired dimensions. For example, in FIG. 12 the diffractive lenses 132 are shown as having the same width as diffractive lenses 116. This example is merely illustrative. Diffractive lenses 116 may have the same or different dimensions than diffractive lenses 132. In FIG. 11, when multi-edge diffractive lenses are used for both diffractive lens 116 and diffractive lens 132, the dimensions of the respective portions of each multi-edge diffractive lens may be different if desired. In FIG. 11, for example, the central portion 136 of diffractive lens 132 has a width that is smaller than the central portion 122 of diffractive lens 116.

If multiple diffractive lenses are included in a single imaging pixel, the diffractive lenses may be the same (e.g., formed from the same material, formed with the same dimensions, etc.) or may be different (e.g., formed from different materials, having different dimensions, etc.). Additionally, the diffractive lenses need not be the same between pixels. For example, a first pixel may have the same diffractive lens arrangement or a different lens arrangement than a second pixel.

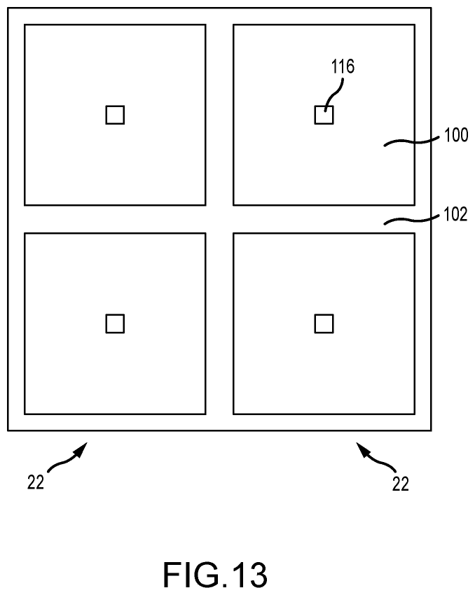

FIGS. 13-15 are top views of illustrative image sensors having light spreading structures. FIG. 13 shows an illustrative example where a single diffractive lens 116 is formed in each imaging pixel. Each imaging pixel includes a respective diffractive lens 116 formed in semiconductor substrate 100 over a respective photodiode. Isolation structures 102 are formed in a grid around each pixel. As shown in FIG. 13, each diffractive lens 116 is completely laterally surrounded by semiconductor substrate 100. The diffractive lenses 116 in FIG. 13 may be single-edge diffractive lenses or multiple-edge diffractive lenses. Each diffractive lens 116 may optionally be covered by another diffractive lens (e.g., diffractive lens 132 in FIGS. 9-12).

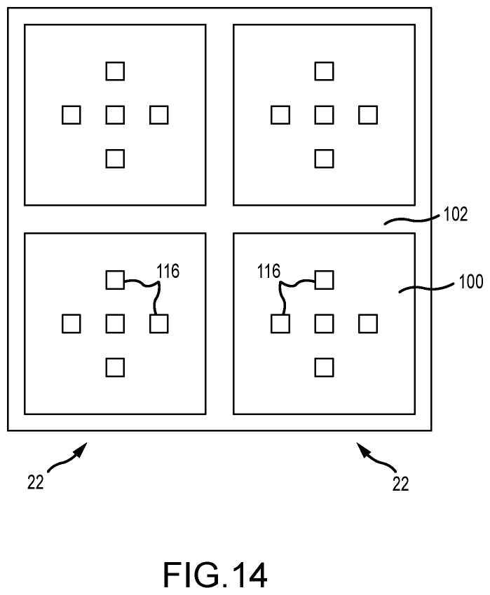

FIG. 14 shows an example where five diffractive lenses are formed in each imaging pixel. Each imaging pixel includes five diffractive lenses 116 formed in semiconductor substrate 100 over a respective photodiode. Isolation structures 102 are formed in a grid around each pixel. As shown in FIG. 14, each diffractive lens 116 is completely laterally surrounded by semiconductor substrate 100. The five diffractive lenses in FIG. 14 are arranged in a cross shape. This example is merely illustrative, and other arrangements for the diffractive lenses may be used if desired. The diffractive lenses 116 in FIG. 14 may be single-edge diffractive lenses or multiple-edge diffractive lenses. Each diffractive lens 116 may optionally be covered by another diffractive lens (e.g., diffractive lens 132 in FIGS. 9-12).

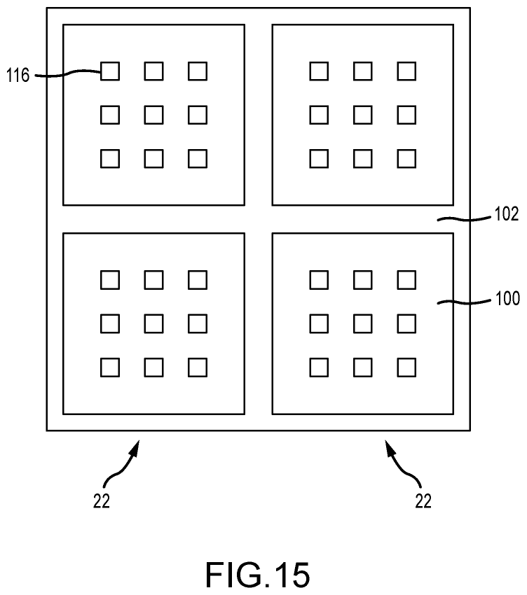

FIG. 15 shows an example where nine diffractive lenses are formed in each imaging pixel. Each imaging pixel includes nine diffractive lenses 116 formed in semiconductor substrate 100 over a respective photodiode. Isolation structures 102 are formed in a grid around each pixel. As shown in FIG. 15, each diffractive lens 116 is completely laterally surrounded by semiconductor substrate 100. The five diffractive lenses in FIG. 15 are arranged in a 3×3 grid. This example is merely illustrative, and other arrangements for the diffractive lenses may be used if desired. The diffractive lenses 116 in FIG. 15 may be single-edge diffractive lenses or multiple-edge diffractive lenses. Each diffractive lens 116 may optionally be covered by another diffractive lens (e.g., diffractive lens 132 in FIGS. 9-12).

In general, each imaging pixel may include any desired number of diffractive lenses (e.g., one, two, three, four, five, six, more than six, nine, more than nine, more than twelve, more than twenty, between three and ten, less than ten, etc.). The diffractive lenses may be arranged in a regular or irregular manner (e.g., the spacing between each pair of adjacent diffractive lenses may be the same across the pixel as in FIG. 15 or may be different). Each diffractive lens may have any desired shape. For example, in FIGS. 13-15 the diffractive lenses are depicted as having a square footprint (e.g., outline when viewed from above). This example is merely illustrative. The diffractive lenses may instead of a non-square rectangular footprint, a circular footprint, an elliptical footprint, or a footprint of any other desired shape.

The imaging pixels described herein may be near-infrared light pixels that detect near-infrared light. Alternatively, the imaging pixels may be visible light pixels that detect visible light. In general, the light spreading structures formed from diffractive lenses may be included in any type of pixel. Regardless of the particular wavelength of interest for the image sensor, the light spreading structures may improve quantum efficiency for the pixels or allow the semiconductor substrate for the image sensor to be thinned without a reduction in efficiency.

The foregoing is merely illustrative of the principles of this invention and various modifications can be made by those skilled in the art without departing from the scope and spirit of the invention.

1. An image sensor comprising:
a semiconductor substrate having a first refractive index;
a photodiode formed in the semiconductor substrate;
a microlens formed over the photodiode, wherein the microlens has a curved upper surface; and
a diffractive lens formed in the semiconductor substrate over the photodiode, wherein the diffractive lens has a second refractive index that is less than the first refractive index; and
an additional diffractive lens formed over the semiconductor substrate, wherein the additional diffractive lens is interposed between the diffractive lens and the curved upper surface.

2. The image sensor defined in claim 1, wherein the semiconductor substrate has a front surface and a back surface and wherein the back surface is interposed between the front surface and the microlens.

3. The image sensor defined in claim 2, wherein the diffractive lens is formed in a trench in the back surface of the semiconductor substrate.

4. The image sensor defined in claim 3, wherein the diffractive lens is contained within the trench and does not extend past the back surface of the semiconductor substrate.

5. The image sensor defined in claim 1, wherein the diffractive lens is completely laterally surrounded by the semiconductor substrate.

6. The image sensor defined in claim 1, wherein the diffractive lens is a first diffractive lens, the image sensor further comprising:
at least a second diffractive lens formed in the semiconductor substrate over the photodiode.

7. The image sensor defined in claim 1, wherein the diffractive lens comprises a material selected from the group consisting of: silicon dioxide and silicon nitride.

8. The image sensor defined in claim 1, wherein the diffractive lens is a multipart diffractive lens comprising a first portion having the second refractive index and a second portion having a third refractive index.

9. The image sensor defined in claim 8, wherein the first portion is an edge portion and the second portion is a center portion and wherein the third refractive index is less than the second refractive index.

10. (canceled)

11. The image sensor defined in claim 1, wherein the additional diffractive lens is surrounded by a dielectric material having a third refractive index, wherein the additional diffractive lens has a fourth refractive index, and wherein the third refractive index is less than the fourth refractive index.

12. The image sensor defined in claim 11, wherein the additional diffractive lens is a multipart diffractive lens having an edge portion with the fourth refractive index and a center portion with a fifth refractive index.

13. The image sensor defined in claim 1, wherein the diffractive lens is a first multipart diffractive lens and the additional diffractive lens is a second multipart diffractive lens.

14. An image sensor comprising a plurality of imaging pixels, each imaging pixel comprising:
a photodiode formed in a semiconductor substrate;
isolation structures in the semiconductor substrate that laterally surround the photodiode;
a microlens formed over the photodiode, wherein the microlens has a curved upper surface;
a first diffractive lens formed in the semiconductor substrate; and
a second diffractive lens formed over the semiconductor substrate, wherein the second diffractive lens is interposed between the curved upper surface of the microlens and the first diffractive lens.

15. The image sensor defined in claim 14, wherein the first diffractive lens has a first refractive index, wherein the semiconductor substrate has a second refractive index, and wherein the second refractive index is greater than the first refractive index.

16. The image sensor defined in claim 15, wherein the second diffractive lens has a third refractive index, wherein the second diffractive lens is surrounded by a material having a fourth refractive index, and wherein the fourth refractive index is less than the third refractive index.

17. The image sensor defined in claim 14, wherein the first diffractive lens is completely laterally surrounded by the semiconductor substrate.

18. The image sensor defined in claim 14, further comprising:
a passivation layer formed between the first and second diffractive lenses.

19-21. (canceled)

22. An image sensor comprising:
a semiconductor substrate;
a photodiode formed in the semiconductor substrate;
a microlens formed over the photodiode, wherein the microlens has a curved upper surface;
a passivation layer on the semiconductor substrate that is interposed between the semiconductor substrate and the microlens; and
a diffractive lens formed over the photodiode, wherein the diffractive lens is interposed between the passivation layer and the curved upper surface of the microlens.

23. The image sensor defined in claim 22, wherein the diffractive lens is surrounded by material used to form the microlens, wherein the diffractive lens has a first refractive index, and wherein the material used to form the microlens has a second refractive index that is less than the first refractive index.

24. The image sensor defined in claim 23, further comprising:
an additional diffractive lens formed in the semiconductor substrate over the photodiode, wherein the additional diffractive lens has a third refractive index and wherein the semiconductor substrate has a fourth refractive index that is greater than the third refractive index.
